(19) United States
(12) Patent Application Publication
(10) Pub. No.: US 2026/0162733 A1
(43) Pub. Date: Jun. 11, 2026

(54) SENSE AMPLIFIER FOR A FLASH MEMORY SYSTEM

(71) Applicant: Silicon Storage Technology, Inc., San Jose, CA (US)

(72) Inventors: Xiaoyan Pi, Shanghai (CN); XIAOZHOU QIAN, Shanghai (CN); Lisa Ll FANG BIAN, Shanghai (CN); ZHENLIN DING, Shanghai (CN)

(21) Appl. No.: 19/026,333

(22) Filed: Jan. 16, 2025

(30) Foreign Application Priority Data
Dec. 11, 2024 (CN) 202411822685.8

(51) Int. Cl. G11C 16/28

(52) U.S. Cl. CPC G11C 16/28

(57) ABSTRACT

In one example, a method comprises generating a first voltage; generating a second voltage; prior to a read operation, charging a first node and a third node to the first voltage and charging a second node and a fourth node to the second voltage, wherein a first capacitor couples the first node and the second node and a second capacitor couples the third node and the fourth node; and during the read operation, discharging the first node through a reference memory cell and discharging the third node through a selected memory cell, wherein the second node tracks the first node through the first capacitor and the fourth node tracks the second node through the second capacitor.

### RELATED APPLICATION

This application claims the benefit of Chinese Patent Application No. 202411822685.8, filed on Dec. 11, 2024, and which is incorporated herein by reference.

### TECHNICAL FIELD

Multiple examples of a sense amplifier for use in a flash memory system are disclosed.

### BACKGROUND

The prior art includes flash memory systems. In a typical flash memory system, a sense amplifier is used to read data from a flash memory cell contained in an array of flash memory cells arranged into rows and columns. Applicant previously proposed a sense amplifier design in U.S. Pat. No. 10,199,109, titled “Low Power Sense Amplifier for a Flash Memory System,” which is incorporated by reference herein. One challenge of that design is that it is not completely effective with a single rail power supply. The design utilizes a precharge voltage at nodes coupled to the reference memory cell and the selected memory cell that are high enough, such as 0.6 V, to generate a certain amount of current through the reference memory cell and selected memory cell. The design also utilizes a reference voltage, VREF, that acts as the trip point of comparators use for the reference memory cell circuit and selected memory cell circuit. VREF should be higher than the precharge voltage. The design also utilizes a power supply of VDDS. To operate the comparators effectively, VDDS should be equal to or greater than VREF+Vthp (the threshold voltage of the PMOS transistors in this design that couple the circuits to VDDS), which is around 1.1 V. However, a typical single rail power supply has a voltage of 1.1V+/−10%, which means that the single rail power supply sometimes will not generate a voltage that is high enough to be used for VDDS in this design.

What is desirable is an improved design that is less dependent on generating a high pre-charge level and that is able to operate within the confines of a single rail power supply of 1.1V+/−10%.

### SUMMARY

Multiple examples of a sense amplifier for use in a flash memory system are disclosed.

### BRIEF DESCRIPTION OF THE DRAWINGS

FIG. 1 depicts a sense amplifier.

FIG. 2 depicts an example waveform of the operation of the sense amplifier of FIG. 1.

FIG. 3 depicts an example of a timing comparison circuit.

FIG. 4 depicts another example of a timing comparison circuit.

FIG. 5 depicts a voltage source.

FIG. 6 depicts another voltage source.

FIG. 7 depicts another sense amplifier.

FIG. 8 depicts an example waveform of the operation of the sense amplifier of FIG. 7.

FIG. 9 depicts a method performed by the sense amplifier of FIG. 1 or the sense amplifier of FIG. 7.

### DETAILED DESCRIPTION

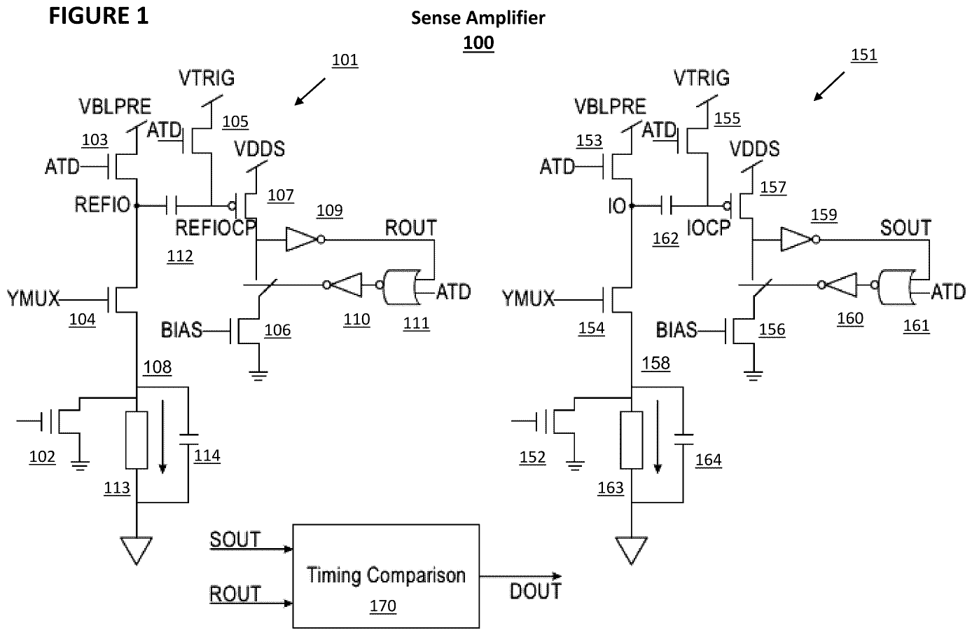

FIG. 1 depicts sense amplifier 100. Sense amplifier 100 comprises reference circuit 101 and read circuit 151.

Reference circuit 101 comprises power sources VBLPRE, VTRIG, and VDDS; reference memory cell 102; NMOS transistors 103, 104, 105, and 106; PMOS transistor 107, reference bit line 108, level shifter 109, inverter 110, NOR gate 111, and capacitor 112, configured as shown. NMOS transistor 103 is controlled through its gate by ATD (address transition detection), NMOS transistor 104 is controlled through its gate by YMUX (Y multiplexor, which is a signal that is asserted when the column containing selected memory cell 152 is selected for an operation), NMOS transistor is controlled through its gate by ATD, and NMOS transistor 105 is controlled through its gate by a control signal, BIAS. NOR gate 111 receives ATD as one of its inputs. Reference bit line 108 is a bit line coupled to reference cell 102 and optionally is connected to a column of other reference cells in a reference cell array (not shown). Reference bit line 108 can draw current, modeled by current source 113, and has an inherent capacitance, modeled by capacitor 114.

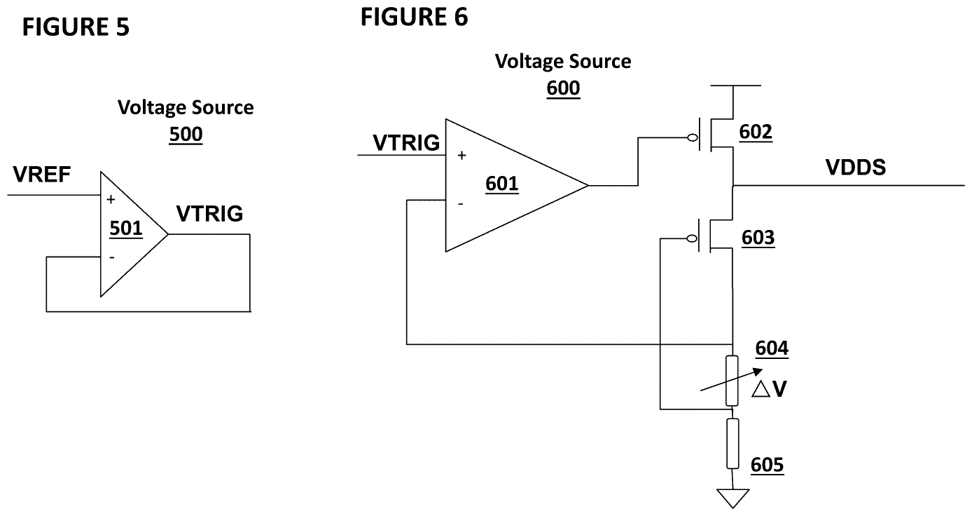

VTRIG optionally can be generated using voltage source shown in FIG. 5. VDDS optionally can be generated using voltage source 600 in FIG. 6. VBLPRE in FIG. 1 can be a reference voltage or the main chip voltage source, vddcore.

Read circuit 151 comprises power sources VBLPRE, VTRIG, and VDDS; selected memory cell 152; NMOS transistors 153, 154, 155, and 156; PMOS transistor 157, bit line 158, level shifter 159, inverter 160, NOR gate 161, and capacitor 162, all configured as shown. NMOS transistor 153 is controlled through its gate by ATD, NMOS transistor 154 is controlled through its gate by YMUX, NMOS transistor 155 is controlled by ATD, and NMOS transistor 156 is controlled by BIAS. NOR gate 161 receives ATD as one of its inputs. Bit line 158 is a bit line coupled to selected memory cell 152 and optionally is connected to a column of other memory cells in a memory cell array (not shown). Bit line 158 can draw current, modeled by current source 163, and has an inherent capacitance, modeled by capacitor 164.

Thus, reference circuit 101 and read circuit 151 are identical, except that reference circuit 101 comprises reference memory cell 102 and is coupled to reference bit line 108, and read circuit 151 comprises selected memory cell 152 and is coupled to bit line 158.

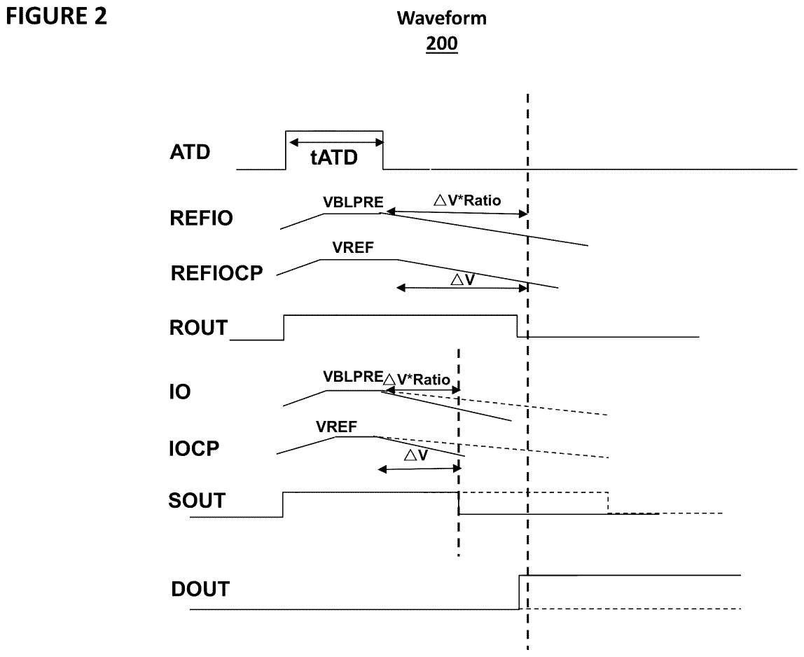

FIG. 2 depicts example waveform 200 to illustrate the operation of sense amplifier 100 in FIG. 1. Prior to a read operation, the BIAS signal is high, which turns on NMOS transistors 106 and 156 and pulls the voltages at the output of inverters 110 and 160 to ground, which causes ROUT and SOUT to go high. At the beginning of a read operation, ATD goes high, which signifies a detection in the change of the address received by the memory system, which coincides with the beginning of a read operation. NMOS transistors 103, 105, 153, and 155 are turned on by ATD, and NMOS transistors 104 and 154 are turned on by YMUX (which indicates that the column containing memory cell 152 has been selected for a read operation). This allows reference cell 102 and selected memory cell 152 to draw current. Concurrently, reference bit line 108 and node REFIO and bit line 158 and node IO will begin charging. As REFIO charges, REFIOCP also will charge through capacitor 112, and as IO charges, IOCP will charge through capacitor 162. BIAS also goes low at the beginning of the read operation. PMOS transistors 107 and 157 will be off, as the voltage on their gates will be high.

ATD will then go low, which shuts off NMOS transistors 103 and 153. Reference bit line 108 will begin discharging through reference cell 102. As it does so, the voltages of REFIO and REFIOCP will decrease, and at some point REFIOCP will drop low enough (below VREF) such that PMOS transistor 107 turns on. This causes ROUT to drop to low. Meanwhile, bit line 158 also is discharging through selected memory cell 152. As it does so, the voltages of IO and IOCP will decrease, and at some point the voltage of IOCP will drop low enough (below VREF) such that PMOS transistor 156 turns on. This causes SOUT to drop to low. Once ROUT/SOUT drop to low, each sense amplifier has a local feedback path (NOR gate 111 and inverter 110 for reference circuit 101 and NOR gate 161 and inverter 160 for read circuit 151) to cut off its bias current, which reduces power consumption compared to certain prior art designs.

There is a race condition between reference circuit 101 and read circuit 151. If selected memory cell 152 draws more current than reference cell 102 (which would be the case if selected memory cell 152 is storing a “1” value), then SOUT will drop to low before ROUT drops to low. But if selected memory cell 152 draws less current than reference cell 102 (which would be the case if selected memory cell 152 is storing a “0” value), then SOUT will drop to low after ROUT drops to low. Thus, the timing of SOUT and ROUT dropping to low indicates the value stored in selected memory cell 152.

SOUT and ROUT are input into timing comparison circuit 170, and the output is DOUT, which indicates the value stored in selected memory cell 152 based on whether SOUT or ROUT dropped to low first.

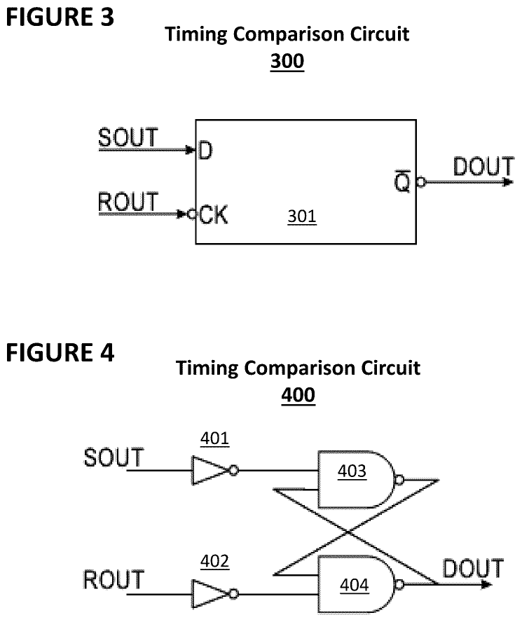

FIG. 3 depicts timing comparison circuit 300, which can be used for timing comparison circuit 170 in FIG. 1. Timing comparison circuit 300 comprises flip-flop 301, with SOUT as the D input, ROUT as the active low clock CK, and DOUT as the output. When ROUT goes low before SOUT, then DOUT will output a “0,” indicating that selected memory cell 152 is storing a “0.” When ROUT goes low after SOUT, then DOUT will output a “1,” indicating that selected memory cell 152 is storing a “1.”

FIG. 4 depicts timing comparison circuit 400, which can be used for timing comparison circuit 170 in FIG. 1. Timing comparison circuit 400 comprises inverters 401 and 402 and NAND gates 403 and 404 configured as shown, with SOUT and ROUT as inputs, and DOUT as the output. When ROUT goes low before SOUT, then DOUT will output a “0,” indicating that selected memory cell 152 is storing a “0.” When ROUT goes low after SOUT, then DOUT will output a “1,” indicating that selected memory cell 152 is storing a “1.”

FIG. 5 depicts voltage source 500 for generating VTRIG from VREF. Voltage source 500 comprises operational amplifier 501 operating as a clamp, with the non-inverting input receiving VREF and the inverting input coupled to the output to generate VTRIG. Thus, VTRIG will be clamped at the voltage VREF.

FIG. 6 depicts voltage source 600 for generating VDDS from VTRIG. Voltage source 600 comprises operational amplifier 601, PMOS transistor 602, PMOS transistor 603, variable resistor 604, and resistor 605. The non-inverting input of operational amplifier 601 receives VTRIG, and the inverting input is coupled to the node between PMOS transistor 603 and variable resistor 604. The resistance of variable resistor is set to cause a voltage drop across variable resistor of ΔV. The output, VDD, is provided at the node between PMOS transistors 603 and 603. VDDS=VREF−ΔV+Vtp, where Vtp is the threshold voltage of PMOS transistor 603. Thus, sense amplifier 100 can be operated using a single rail power supply that provides VREF, where the single rail power supply can provide a voltage of 1.1V+/−10% as is common in the prior art.

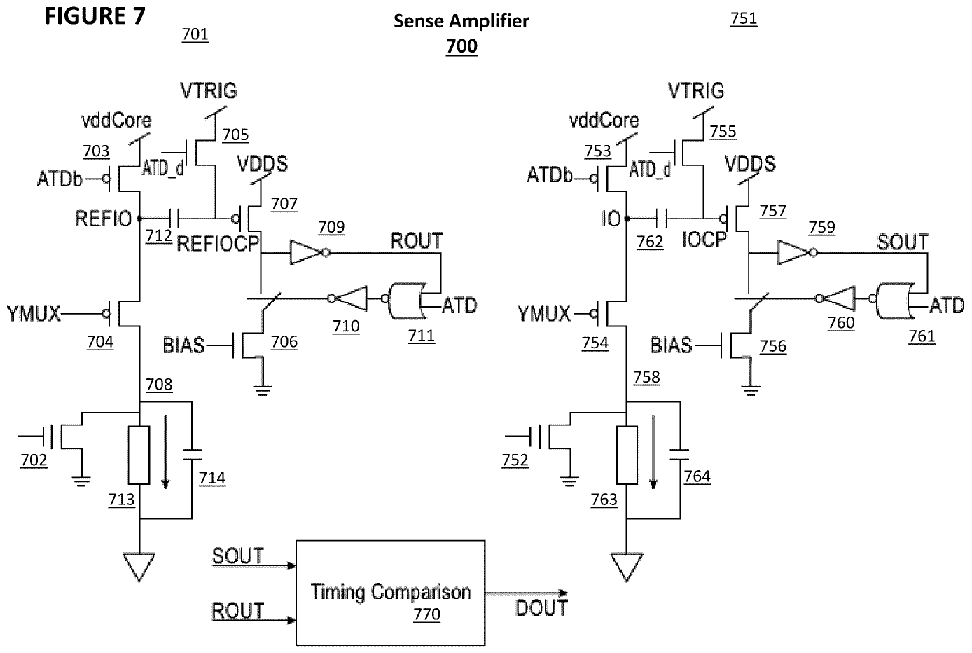

FIG. 7 depicts sense amplifier 700. Sense amplifier 700 comprises reference circuit 701 and read circuit 751.

Reference circuit 701 comprises power sources vddcore, VTRIG, and VDDS; reference memory cell 702; PMOS transistors 703, 704, and 707; NMOS transistors 705 and 706; reference bit line 708; level shifter 709; inverter 710; NOR gate 711; and capacitor 712, configured as shown. PMOS transistor 703 is controlled through its gate by ATDb (the complement to ATD, address transition detection), PMOS transistor 704 is controlled through its gate by YMUX, NMOS transistor 705 is controlled through its gate by ATD_d, and NMOS transistor 706 is controlled through its gate by BIAS. NOR gate 711 receives ATD as one of its inputs. Reference bit line 708 is a bit line coupled to reference cell 702 and optionally is connected to a column of other reference cells in a reference cell array (not shown). Reference bit line 708 can draw current, modeled by current source 713, and has an inherent capacitance, modeled by capacitor 714.

VTRIG optionally can be generated using voltage source shown in FIG. 5. VDDS optionally can be generated using voltage source 600 in FIG. 6. Vddcore is the main chip voltage source.

Read circuit 751 comprises power sources vddcore, VTRIG, and VDDS; selected memory cell 752; PMOS transistors 753, 754, and 757; NMOS transistors 755 and 756; bit line 758; level shifter 759; inverter 760; NOR gate 761; and capacitor 762, all configured as shown. PMOS transistor 753 is controlled through its gate by ATDb, PMOS transistor 754 is controlled through its gate by YMUX, NMOS transistor 755 is controlled through its gate by ATD_d, and NMOS transistor 756 is controlled through its gate by BIAS. NOR gate 761 receives ATD as one of its inputs. Bit line 758 is a bit line coupled to selected memory cell 752 and optionally is connected to a column of other memory cells in a memory cell array (not shown). Bit line 758 can draw current, modeled by current source 763, and has an inherent capacitance, modeled by capacitor 764.

Thus, reference circuit 701 and read circuit 751 are identical, except that reference circuit 701 comprises reference memory cell 702 and is coupled to refence bit line 708, and read circuit 751 comprises selected memory cell 752 and is coupled to bit line 758.

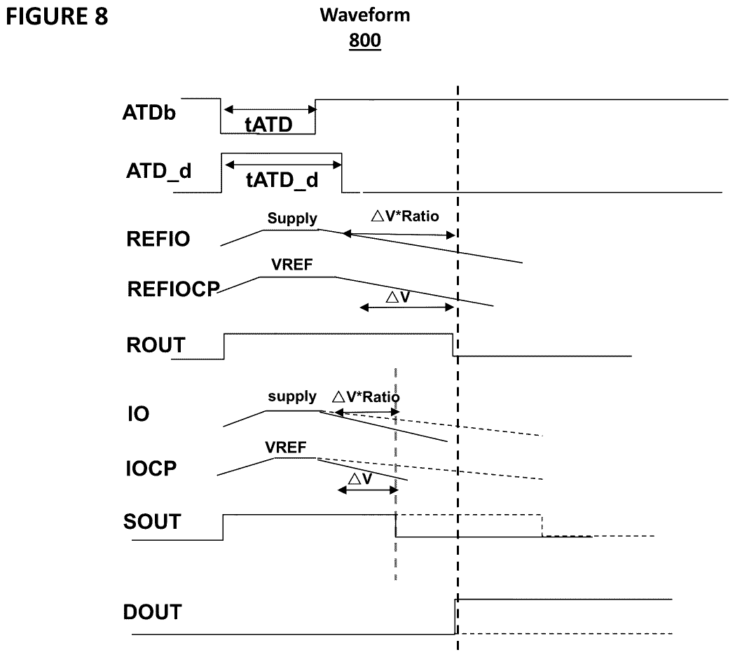

FIG. 8 depicts example waveform 800 to illustrate the operation of sense amplifier 700 in FIG. 7. Prior to a read operation, the BIAS signal is high, which turns on NMOS transistors 706 and 756 and pulls the voltage at the output of inverters 710 and 760 to ground, which causes ROUT and SOUT to go high. At the beginning of a read operation, ATD and ATD_d go high and ATDb goes low, which signifies a detection in the change of the address received by the memory system, which coincides with the beginning of a read operation. ATD-d is generated from ATD with a delay added to the falling edge. PMOS transistors 703 and 753 are turned on by ATDb, NMOS transistors 705 and 755 are turned on by ATD_d, and PMOS transistors 704 and 754 are turned on by YMUX (which indicates that the column containing memory cell 752 has been selected for a read operation). This allows reference cell 702 and selected memory cell 752 to draw current. Concurrently, reference bit line 708 and node REFIO and bit line 758 and node IO will begin charging. As REFIO charges, REFIOCP also will charge through capacitor 712. As IO charges, IOCP will charge through capacitor 762. BIAS also goes low at the beginning of the read operation. At this juncture, PMOS transistors 707 and 757 are off, as the voltage on their gates will be high.

ATD and will then go low and ATDb will go high, which shuts off PMOS transistors 703 and 753. Moments later, ATD_d will go low, which shuts off NMOS transistors 705 and 755. Reference bit line 708 will begin discharging through reference cell 702. As it does so, the voltages of REFIO and REFIOCP will decrease, and at some point REFIOCP will drop low enough (below VREF) such that PMOS transistor 707 turns on. This causes ROUT to drop to low. Meanwhile, bit line 758 also is discharging through selected memory cell 752. As it does so, the voltages of IO and IOCP will decrease, and at some point the voltage of IOCP will drop low enough (below VREF) such that PMOS transistor 757 turns on. This causes SOUT to drop to low. Once ROUT/SOUT drop to low, each sense amplifier has a local feedback path (NOR gate 711 and inverter 710 for reference circuit 701 and NOR gate 761 and inverter 760 for read circuit 751) to cut off its bias current, which reduces the power consumption compared to certain prior art designs.

There is a race condition between reference circuit 701 and read circuit 751. If selected memory cell 752 draws more current than reference cell 702 (which would be the case if selected memory cell 752 is storing a “1” value), then SOUT will drop to low before ROUT drops to low. But if selected memory cell 752 draws less current than reference cell 702 (which would be the case if selected memory cell 752 is storing a “0” value), then SOUT will drop to low after ROUT drops to low. Thus, the timing of SOUT and ROUT dropping to low indicates the value stored in selected memory cell 752.

SOUT and ROUT are input into timing comparison circuit 770, and the output is DOUT, which indicates the value stored in selected memory cell 752 based on whether SOUT or ROUT dropped to low first.

Timing comparison circuit 770 can be implemented with time comparison circuit 300 of FIG. 3, timing comparison circuit 400 of FIG. 4, or another timing comparison circuit.

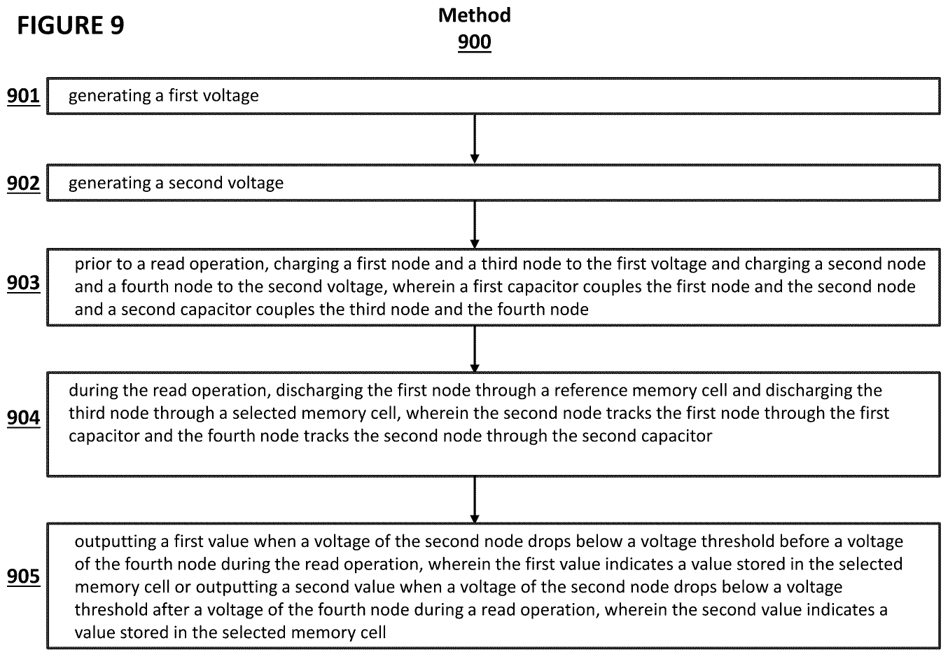

FIG. 9 depicts method 900 that can be performed by sense amplifier 100 of FIG. 1 or sense amplifier 700 of FIG. 7. Method 900 comprises generating a first voltage (901); generating a second voltage (902); prior to a read operation, charging a first node and a third node to the first voltage and charging a second node and a fourth node to the second voltage, wherein a first capacitor couples the first node and the second node and a second capacitor couples the third node and the fourth node (903); during the read operation, discharging the first node through a reference memory cell and discharging the third node through a selected memory cell, wherein the second node tracks the first node through the first capacitor and the fourth node tracks the second node through the second capacitor (904); and outputting a first value when a voltage of the second node drops below a voltage threshold before a voltage of the fourth node during the read operation, wherein the first value indicates a value stored in the selected memory cell, or outputting a second value when a voltage of the second node drops below a voltage threshold after a voltage of the fourth node during a read operation, wherein the second value indicates a value stored in the selected memory cell (905).

Materials, processes and numerical examples described above are mere examples, and should not be deemed to limit the claims. As used herein, the terms “over” and “on” both inclusively include “directly on” (no intermediate materials, elements or space disposed there between) and “indirectly on” (intermediate materials, elements or space disposed there between). Likewise, the term “adjacent” includes “directly adjacent” (no intermediate materials, elements or space disposed there between) and “indirectly adjacent” (intermediate materials, elements or space disposed there between). For example, forming an element “over a substrate” can include forming the element directly on the substrate with no intermediate materials/elements there between, as well as forming the element indirectly on the substrate with one or more intermediate materials/elements there between.

What is claimed is:

1. A system, comprising:
a first power source generating a first voltage;
a second power source generating a second voltage;
a reference circuit comprising:
a first capacitor coupled between a first node and a second node, wherein prior to a read operation, the first node is pre-charged to the first voltage and the second node is pre-charged to the second voltage; and
a reference memory cell;
wherein during a read operation, the first node is discharged through the reference memory cell and the second node tracks the first node through the first capacitor;
a read circuit comprising:
a second capacitor coupled between a third node and a fourth node, wherein prior to the read operation, the third node is pre-charged to the first voltage and the fourth node is pre-charged to the second voltage; and
a selected memory cell to be read;
wherein during the read operation, the third node is discharged through the selected memory cell and the fourth node tracks the third node through the second capacitor; and
a timing comparison circuit for outputting a first value when a voltage of the second node drops below a voltage threshold before a voltage of the fourth node during a read operation and for outputting a second value when a voltage of the second node drops below the voltage threshold after a voltage of the fourth node during a read operation, wherein the first value and second value indicate values stored in the selected memory cell.

2. The system of claim 1, wherein the timing comparison circuit comprises a flip-flop receiving a first voltage from the reference circuit as an active low clock input and a second voltage from the read circuit as a D input and outputting the first value or the second value.

3. The system of claim 1, wherein the timing comparison circuit comprises:
a first NAND gate;
a second NAND gate, wherein an output of the first NAND gate is provided to the second NAND gate as an input and an output of the second NAND gate is provided to the first NAND gate as an input;
a first inverter receiving a first voltage from the reference circuit and providing a first output as an input to the first NAND gate; and
a second inverter receiving a second voltage from the read circuit and providing a second output as an input to the second NAND gate, wherein the second NAND gate outputs the first value or the second value.

4. The system of claim 1, wherein the selected memory cell is coupled to the timing comparison circuit during a read operation by a transistor controlled by a signal from a multiplexor.

5. The system of claim 4, wherein the reference memory cell is coupled to the timing comparison circuit during a read operation by a transistor controlled by the signal from the multiplexor.

6. The system of claim 1, wherein the first node is coupled to the first power source by a transistor controlled by an address transition detection signal.

7. The system of claim 6, wherein the third node is coupled to the first power source by a transistor controlled by the address transition detection signal.

8. The system of claim 1, wherein the second node is coupled to the second power source by a transistor controlled by an address transition detection signal.

9. The system of claim 8, wherein the fourth node is coupled to the second power source by a transistor controlled by the address transition detection signal.

10. The system of claim 1, wherein the second power source comprises an operational amplifier comprising a non-inverting input receiving a reference voltage, an inverting input, and an output coupled to the inverting input, wherein the output provides the second voltage.

11. A method, comprising:
generating a first voltage;
generating a second voltage;
prior to a read operation, charging a first node and a third node to the first voltage and charging a second node and a fourth node to the second voltage, wherein a first capacitor couples the first node and the second node and a second capacitor couples the third node and the fourth node; and
during the read operation, discharging the first node through a reference memory cell and discharging the third node through a selected memory cell, wherein the second node tracks the first node through the first capacitor and the fourth node tracks the second node through the second capacitor.

12. The method of claim 11, comprising:
outputting a first value when a voltage of the second node drops below a voltage threshold before a voltage of the fourth node during the read operation, wherein the first value indicates a value stored in the selected memory cell.

13. The method of claim 12, wherein the outputting is performed by a timing comparison circuit.

14. The method of claim 13, wherein the timing comparison circuit comprises a flip-flop.

15. The method of claim 13, wherein the timing comparison circuit comprises:
a first NAND gate;
a second NAND gate, wherein an output of the first NAND gate is provided to the second NAND gate as an input and an output of the second NAND gate is provided to the first NAND gate as an input;
a first inverter receiving a first voltage from a reference circuit and providing a first output as an input to the first NAND gate; and
a second inverter receiving a second voltage from a read circuit and providing a second output as an input to the second NAND gate, wherein the second NAND gate outputs the first value.

16. The method of claim 11, comprising:
outputting a second value when a voltage of the second node drops below a voltage threshold after a voltage of the fourth node during a read operation, wherein the second value indicates a value stored in the selected memory cell.

17. The method of claim 16, wherein the outputting is performed by a timing comparison circuit.

18. The method of claim 17, wherein the timing comparison circuit comprises a flip-flop.

19. The method of claim 17, wherein the timing comparison circuit comprises:
a first NAND gate;
a second NAND gate, wherein an output of the first NAND gate is provided to the second NAND gate as an input and an output of the second NAND gate is provided to the first NAND gate as an input;
a first inverter receiving a first voltage from a reference circuit and providing a first output as an input to the first NAND gate; and
a second inverter receiving a second voltage from a read circuit and providing a second output as an input to the second NAND gate, wherein the second NAND gate outputs the second value.

20. The method of claim 11, wherein the generating a second voltage is performed by an operational amplifier comprising a non-inverting input receiving a reference voltage, an inverting input, and an output coupled to the inverting input, wherein the output provides the second voltage.
